(19) United States
(12) Patent Application Publication
(10) Pub. No.: US 2026/0062835 A1
(43) Pub. Date: Mar. 5, 2026

(54) FLUID SYSTEMS, SEMICONDUCTOR PROCESSING SYSTEMS INCLUDING FLUID SYSTEMS, FLOW CONTROL METHODS AND RELATED COMPUTER PROGRAM PRODUCTS

(71) Applicant: ASM IP Holding B.V., Almere (NL)

(72) Inventors: Krishnaswamy Mahadevan, Tempe, AZ (US); Fan Gao, Chandler, AZ (US); Kishor Patil, Chandler, AZ (US)

(21) Appl. No.: 19/309,241

(22) Filed: Aug. 25, 2025

Related U.S. Application Data
(60) Provisional application No. 63/687,563, filed on Aug. 27, 2024.

(51) Int. Cl. C30B 25/16; C23C 16/448; C23C 16/52; H01L 21/67

(52) U.S. Cl. CPC C30B 25/165; C23C 16/4481; C23C 16/52

(57) ABSTRACT

A fluid system includes a conduit, a concentration sensor coupled to the conduit, and a processor. The processor is disposed in communication with the concentration sensor and responsive to instructions recorded on a memory to receive a concentration control selection, further receive a signal indicative of concentration of a fluid constituent entrained in a fluid constituent-carrier in a fluid conveyed by the conduit, and determine concentration of the fluid constituent. The concentration of the fluid constituent is controlled by throttling one of (a) mass flow rate of the fluid, (b) pressure of the fluid constituent-carrier, and (c) the mass flow rate of the fluid and the pressure of the fluid constituent-carrier based on the concentration control selection when the concentration differs from a predetermined concentration value by more than a predetermined concentration differential. Semiconductor processing systems, flow control methods, and related computer program products are also described.

### CROSS-REFERENCE TO RELATED APPLICATION(S)

This application claims the benefit of U.S. Provisional Application 63/687,563 filed on Aug. 27, 2024, the entire contents of which are incorporated herein by reference.

### FIELD

The present disclosure generally relates to fluid systems, and more particularly, to controlling fluid flow in fluid systems.

### BACKGROUND OF THE DISCLOSURE

Fluid systems are commonly employed to communicate fluids between fluid sources and fluid destinations, such as precursors employed in gas phase reactors to deposit material layers onto substrates, generally using flow control devices like metering valves. Metering valves typically control fluid flow in by changing effective flow area through the fluid systems, such as by moving a valve member within a movement range wherein effective flow area may be controlled with accuracy sufficient to control the fluid flow. In some fluid systems the range within a flow control device is accurate may be undersized with respect to the flow requirements of the fluid destination. In such systems the fluid system may constrain the fluid destination, for example by limiting throughput or speed of the gas phase reactor serviced by the fluid system. While constraining flow through the fluid system according to accuracy of the flow control device is generally acceptable insofar as ensuring accuracy of fluid flow through the fluid system, this can increase cost of ownership of the gas phage reactor.

Such systems and methods have generally been considered suitable for their intended purpose. However, there remains a need in the art for improved fluid systems, semiconductor processing systems, flow control methods, and related computer program products. The present disclosure provides a solution to this need.

### SUMMARY OF THE DISCLOSURE

A fluid system is provided. The fluid system includes a conduit, a concentration sensor coupled to the conduit, and a processor. The processor is disposed in communication with the concentration sensor and is responsive to instructions recorded on a memory to receive a concentration control selection, further receive a signal indicative of concentration of a fluid constituent entrained in a fluid constituent-carrier in a fluid conveyed by the conduit, and determine concentration of the fluid constituent. The concentration of the fluid constituent is controlled by throttling one of (a) mass flow rate of the fluid, (b) pressure of the fluid constituent-carrier, and (c) the mass flow rate of the fluid and the pressure of the fluid constituent-carrier based on the concentration control selection when the concentration differs from a predetermined concentration value by more than a predetermined concentration differential.

In addition to one or more of the features described above, or as an alternative, further examples of the fluid system may include that the concentration sensor includes an acoustic transmitter coupled to the conduit. An acoustic receiver may be coupled, for example acoustically, to the transmitter by the conduit. In some embodiments, the fluid system comprises an acoustic transmitter coupled to the conduit, and an acoustic receiver coupled to the transmitter by the conduit.

In addition to one or more of the features described above, or as an alternative, further examples of the fluid system may include an illuminator coupled to the conduit. A detector may be coupled, for example optically, to the illuminator by the conduit.

In addition to one or more of the features described above, or as an alternative, further examples of the fluid system may include a liquid vessel fluidly coupled to the concentration sensor, a pressure control device fluidly coupled to the liquid vessel and therethrough to the concentration sensor, and a mass flow control device fluidly coupled to the concentration sensor and therethrough to the pressure control device by the liquid vessel.

In addition to one or more of the features described above, or as an alternative, further examples of the fluid system may include that the concentration sensor is operably coupled to the pressure control device and the mass flow control device.

In addition to one or more of the features described above, or as an alternative, further examples of the fluid system may include a liquid material layer precursor contained in the liquid vessel and a carrier source including a carrier fluid fluidly coupled to the liquid vessel by the pressure control device. The liquid material layer precursor may include a silicon-containing material layer precursor, a germanium-containing material layer precursor, or a dopant-containing material layer precursor. The carrier source may include hydrogen (H₂) gas, nitrogen (N₂) gas, a noble gas, or a mixture into one or more of the aforementioned gases. The carrier source may further be configured to communicate a flow of the carrier fluid to the liquid vessel to vaporize the liquid material layer precursor contained in the liquid vessel.

In addition to one or more of the features described above, or as an alternative, further examples of the fluid system may include a gas phase reactor having a single-wafer crossflow architecture coupled to the mass flow control device and therethrough to the pressure control device through the concentration sensor and the liquid vessel.

In addition to one or more of the features described above, or as an alternative, further examples of the fluid system may include a wired or wireless link communicatively coupling the concentration sensor to the pressure control device and the mass flow control device.

In addition to one or more of the features described above, or as an alternative, further examples of the fluid system may include a mass flow control device fluidly coupled to the concentration sensor. The instructions recorded on the memory may further cause the processor to compare the determined concentration to a predetermined concentration value and throttle mass flow rate of the fluid conveyed by the conduit when the determined concentration differs from a predetermined concentration value by more than the predetermined concentration differential when the received concentration control selection is the (a) mass flow rate of the fluid.

In addition to one or more of the features described above, or as an alternative, further examples of the fluid system may include that throttling mass flow rate of the fluid includes determining a mass flow setpoint using the concentration and communicating the mass flow setpoint to the mass flow control device.

In addition to one or more of the features described above, or as an alternative, further examples of the fluid system may include a pressure control device fluidly coupled to the concentration sensor. The instructions recorded on the memory may further cause the processor to compare the concentration to a predetermined concentration value and throttle pressure of the fluid constituent-carrier when the concentration differs from the predetermined concentration value by more than the predetermined concentration differential when the received concentration control selection is the (b) pressure of the fluid constituent-carrier.

In addition to one or more of the features described above, or as an alternative, further examples of the fluid system may include that throttling pressure of the fluid constituent-carrier includes determining a pressure setpoint using the concentration and communicating the pressure setpoint to the pressure control device.

In addition to one or more of the features described above, or as an alternative, further examples of the fluid system may include a pressure control device fluidly coupled to the concentration sensor and a mass flow device fluidly coupled to the pressure control device through the concentration sensor. The instructions recorded on the memory further cause the processor to compare the concentration to a predetermined concentration value; an throttle both mass flow rate of the fluid and pressure of the fluid constituent-carrier when the concentration differs from the predetermined concentration value by more than the predetermined concentration differential when the received concentration control selection is the (c) the mass flow rate of the fluid and the pressure of the fluid constituent-carrier.

In addition to one or more of the features described above, or as an alternative, further examples of the fluid system may include that the throttling both mass flow rate of the fluid and the pressure of the fluid constituent-carrier includes determining a tandem mass flow setpoint and a tandem pressure setpoint using the concentration. The tandem mass flow setpoint may be communicated to the mass flow control device and the tandem pressure control setpoint communicated to the pressure control device.

In addition to one or more of the features described above, or as an alternative, further examples of the fluid system may include concentration control device housing enclosing the processor and the concentration sensor.

In addition to one or more of the features described above, or as an alternative, further examples of the fluid system may include a concentration control device housing enclosing the concentration sensor and a wired or wireless link coupled to the concentration sensor coupling the concentration sensor to the processor.

In addition to one or more of the features described above, or as an alternative, further examples of the fluid system may include a concentration control device housing enclosing the concentration sensor. A gas phase reactor may be coupled to the conduit. A system controller including the processor may be coupled to the gas phase reactor. A wired or wireless link may couple the processor to the concentration control device housing enclosing the concentration sensor and therethrough to the concentration sensor.

In addition to one or more of the features described above, or as an alternative, further examples of the fluid system may include a wired or wireless link coupled to the concentration sensor. A mass flow control device housing or a pressure control device housing may enclose the processor. The mass flow control device housing or the pressure control device housing may couple processor may to the concentration sensor.

A semiconductor processing system is provided. The semiconductor processing system includes a fluid system as described above further including a liquid vessel fluidly coupled to the conduit and a silicon-containing material layer precursor in a liquid state contained within the liquid vessel. A gas phase reactor is coupled to the conduit, an exhaust source coupled to the gas phase reactor and therethrough to the fluid system, and a system controller including the processor is operatively coupled to the gas phase reactor.

A flow control method is provided. The flow control method includes, at a fluid system as described above, receiving a concentration control selection at the processor, receiving a signal indicative of concentration of a fluid constituent entrained in a fluid constituent-carrier in a fluid conveyed by the conduit at the processor, and determining concentration of the fluid constituent using the processor. The concentration of the fluid constituent conveyed by the conduit is controlled by throttling one of (a) mass flow rate of the fluid, (b) pressure of the fluid constituent-carrier, and (c) the mass flow rate of the fluid and the pressure of the fluid constituent-carrier based on the concentration control selection when the determined concentration differs from a predetermined concentration value by more than a predetermined concentration differential.

In addition to one or more of the features described above, or as an alternative, further examples of the method may include that the fluid constituent includes a vaporized liquid silicon-containing material layer precursor, a vaporized liquid germanium-containing material layer precursor, and/or a vaporized liquid dopant-containing material layer precursor.

In addition to one or more of the features described above, or as an alternative, further examples of the method may include that the fluid constituent includes a vaporized liquid material layer precursor. The method may further include communicating the fluid to a gas phase reactor with the conduit and depositing a material layer onto a substrate supported in the gas phase reactor using the vaporized liquid material layer precursor with an epitaxial deposition technique.

A computer program product is provided. The computer program product includes a non-transitory machine-readable medium having a plurality of program modules recorded thereon that, when read by a processor, cause the processor to receive a concentration control selection; receive, at the processor, a signal indicative of concentration of a fluid constituent entrained in a fluid constituent-carrier in a fluid conveyed by a conduit from a concentration sensor coupled to the conduit and disposed in communication with the sensor; determine concentration of the fluid constituent; and control concentration of the fluid constituent convey by the conduit by throttling one of (a) mass flow rate of the fluid, (b) pressure of the fluid constituent-carrier, and (c) the mass flow rate of the fluid and the pressure of the fluid constituent-carrier based on the concentration control selection when the concentration differ from a predetermined concentration value by more than a predetermined concentration differential.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including fluid system and a gas phase reactor in accordance with the present disclosure, showing the fluid system controlling mass flow rate of a vaporized liquid fluid constituent entrained in a fluid constituent-carrier to the gas phase reactor;

FIG. 2 is a schematic view of the gas phase reactor and a controller of the semiconductor processing system of FIG. 1 according to an example of the disclosure, showing a gas phase reactor having a single substrate crossflow arrangement;

FIG. 3 is a block diagram of the fluid system of FIG. 1 according to an example of the present disclosure, showing a liquid vessel coupling a pressure control device (PCD) to a mass flow control device (MFC) through a concentration control device (CCD);

FIG. 4 to FIG. 6 are schematic views of the PCD, MFC, and CCD of FIG. 3 according to examples of the disclosure, showing the CCD communication setpoints for the PCD and the MFC using concentration of the fluid constituent entrained within the fluid constituent-carrier; and

FIG. 7 to FIG. 11 are a block diagram of a flow control method, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

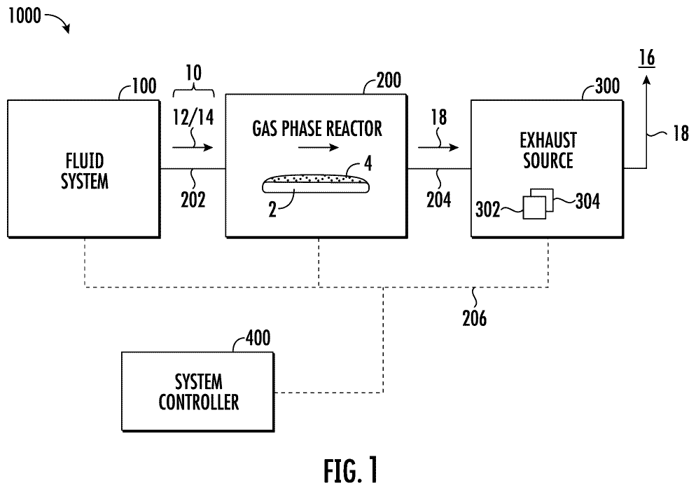

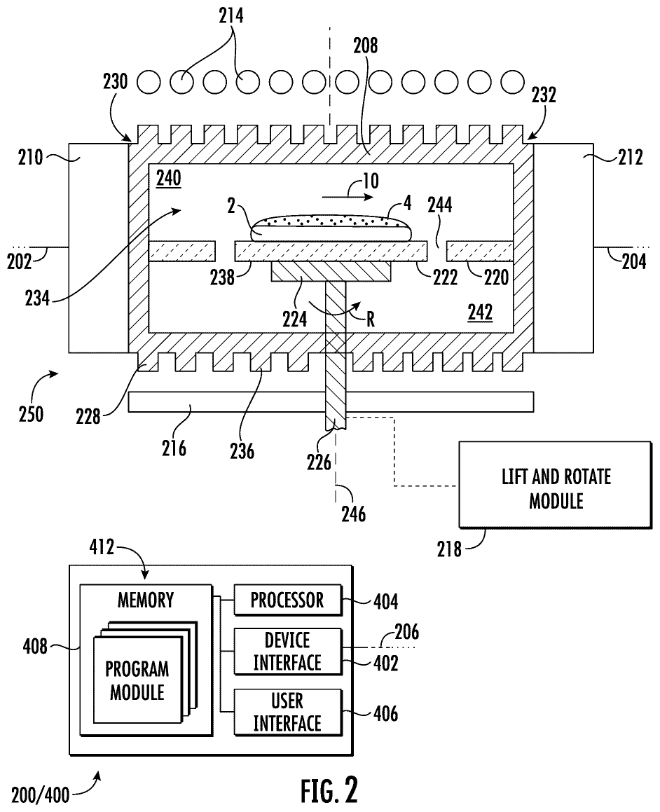

Reference will now be made to the drawings wherein like reference numerals identify similar structural features or aspects of the subject disclosure. For purposes of explanation and illustration, and not limitation, a partial view of a fluid system in accordance with the present disclosure is shown in FIG. 1 and is designated generally by reference character 100. Other examples of fluid systems, semiconductor processing systems including fluid systems, and related flow control methods and computer program products in accordance with the present disclosure, or aspects thereof, are provided in FIG. 2 to FIG. 10, as will be described. The systems and methods of the present disclosure may be used to control flow of fluids in fluid systems, such as in fluid systems used to communicate vaporized liquid material layer precursors in semiconductor processing systems, though the present disclosure is not limited to any particular type of fluid or to semiconductor processing systems in general.

Referring to FIG. 1, a semiconductor processing system 1000 including the fluid system 100 in accordance with examples of the present disclosure is shown. As shown in FIG. 1 the semiconductor processing system 1000 includes the fluid system 100, a gas phase reactor 200, an exhaust source 300, and a system controller 400. The fluid system 100 is coupled to the gas phase reactor 200 by a supply conduit 202 and is configured to communicate a flow of a fluid 10 (e.g., a fluid constituent 12 entrained in a fluid constituent-carrier 14) to the gas phase reactor 200 using the supply conduit 202. The gas phase reactor 200 is coupled to exhaust source 300 by an exhaust conduit 204 and is configured to deposit a material layer 4 onto a substrate 2 supported within the gas phase reactor 200 using the fluid 10. The exhaust source 300 couples the gas phase reactor 200 to an external environment 16 outside of the semiconductor processing system 1000 and is configured to communicate residual fluid constituent and/or reaction products 18 issued by the gas phase reactor 200 to the external environment 16, for example through one or more vacuum pump 302 and an abatement device 304 such as a burn box and/or a scrubber. The system controller 400 is operably associated with the fluid system 100 by a wired or wireless link 206 and may be configured to control flow of the fluid 10 to the gas phase reactor 200, for example by controlling concentration of the fluid constituent 12 entrained in the fluid constituent-carrier 14 communicated to the gas phase reactor 200.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SIC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the gas phase reactor 200 is shown according to an example of the present disclosure. In the illustrated example the gas phase reactor 200 has a single-substrate crossflow architecture 250 and includes a chamber body 208, an injection flange 210, and an exhaust flange 212. As shown and described herein the gas phase reactor 200 also includes an upper heater element array 214, a lower heater element array 216, a lift and rotate module 218, a divider 220, a substrate support 222, a support member 224, and a shaft member 226. Although shown and described herein as including certain features and having a specific arrangement, it is to be understood and appreciated that the gas phase reactor 200 may include additional features and/or omit certain features shown and described herein, and/or have a different arrangement (e.g., a downflow or multi-substrate architecture) in other examples and remain within the scope of the present disclosure.

The chamber body 208 is formed from a transparent material 228 (e.g., a material transparent to electromagnetic material within an infrared waveband) and extends between an injection end 230 and a longitudinally opposite exhaust end 232 of the chamber body 208. The injection flange 210 abuts the injection end 230 of the chamber body 208 and is coupled to the fluid system 100 (shown in FIG. 1) by the supply conduit 202. The exhaust flange 212 abuts the exhaust end 232 of the chamber body 208, is fluidly coupled to the injection flange 210 by an interior 234 of the chamber body 208, and is coupled to the exhaust source 300 (shown in FIG. 1) by the exhaust conduit 204. In certain examples the transparent material 228 forming the chamber body 208 may include (or consist of or consist essentially of) a ceramic material such as fused silica, quartz, and sapphire by way of non-limiting examples. In accordance with certain examples, the chamber body 208 may have one or more external rib 236. In such examples the one or more external rib 236 may extend laterally about an exterior of the chamber body 208. In such examples the one or more external rib 236 may further be one of a plurality of external ribs 236 each extending laterally about an exterior of the chamber body 208 and longitudinally spaced apart from one another between the injection end 230 and the exhaust end 232 of the chamber body 208. It is contemplated that the injection flange 210 may be as shown and described in U.S. Pat. No. 11,053,591 to Ma et al., issued on Jul. 6, 2021, the contents of which is incorporated herein by reference in its entirety. It is also contemplated that the exhaust flange 212 may be as shown and described in U.S. Pat. No. 10,612,136 to Sreeram et al., issued on Apr. 7, 2020, the contents of which is also incorporated herein by reference in its entirety.

The divider 220 is formed from an opaque material 238 (e.g., a material opaque to electromagnetic radiation within an infrared waveband) and is arranged within the interior 234 of the chamber body 208. The divider 220 further divides the interior 234 of the chamber body 208 into an upper chamber 240 and a lower chamber 242. It is contemplated that the divider 220 define therethrough a divider aperture 244. The divider aperture 244 in turn fluidly couple the upper chamber 240 of the chamber body 208 to the lower chamber 242 of the chamber body 208, extends about the substrate support 222 and may be substantially circular in shape. In certain examples the opaque material 238 forming the divider 220 may include (or consist of or consist essentially of) a ceramic material. Examples suitable opaque materials include bulk silicon carbide, bulk pyrolytic carbon with a silicon carbide coating, and bulk graphite with a silicon carbide coating.

It is contemplated that the substrate support 222 be supported within the interior 234 of the chamber body 208 for rotation R about a rotation axis 246. More specifically, the substrate support 222 is a arranged within the divider aperture 244 extending through the divider 220 and support therein for rotation R about the rotation axis 246. It is contemplated that the substrate support 222 also be formed from an opaque material (e.g., a material opaque to electromagnetic radiation within an infrared waveband) and in this respect may include (or consist of or consist essentially of) a ceramic material, such as silicon carbide. In accordance with certain examples, the opaque material 238 may also include (or consist of or consist essentially of) a bulk carbonaceous material, such as bulk pyrolytic carbon or bulk graphite with a silicon carbide coating. In certain examples the substrate support 222 may be as shown and described in U.S. Patent Application Publication No. 2022/0352006 A1 to Huang et al., filed on Apr. 27, 2022, the contents of which are incorporated herein by reference in its entirety.

The support member 224 is formed from a transparent material, for example the transparent material 228, and is arranged within the lower chamber 242 of the chamber body 208. The support member 224 is further arranged along the rotation axis 246 and fixed in rotation about the rotation axis 246 relative to the substrate support 222. It is contemplated that the shaft member 226 may also be formed from a transparent material, for example the transparent material 228, further be arranged along the rotation axis 246 and fixed in rotation about the rotation axis 246 relative to the support member 224, and additionally extend through a lower wall of the chamber body 208. It is further contemplated that the shaft member 226 operably couple the substrate support 222 to the lift and rotate module 218 through the support member 224. The lift and rotate module 218 may in turn be configured to rotate the substrate support 222 about the rotation axis 246. The lift and rotate module 218 may further be configured to seat and unseat substrates (e.g., the substrate 2) from the substrate support 222, for example using a plurality of lift pins slidably received in the substrate support 222 and a lift pin actuator operably associated with the lift and rotate module 218. Examples of suitable lift and rotate modules, lift pins, and lift pin actuators include those shown and described in U.S. Patent Application Publication No. 2019/0051555 A1 to Hill et al., the contents of which is incorporated herein by reference in its entirety.

The upper heater element array 214 is supported above the chamber body 208 and is configured to communicate radiant heat into the interior 234 of the chamber body 208, for example by generating electromagnetic radiation within an infrared waveband and communicating the electromagnetic radiation through the transparent material 228. In this respect it is contemplated that the upper heater element array 214 include a plurality of filament-type linear lamps each supported above the chamber body 208. In certain examples of the present disclosure the plurality of filament-type linear lamps may extend longitudinally between the injection end 230 and the exhaust end 232 of the chamber body 208. It is further contemplated that the plurality of filament-type linear lamps be laterally spaced apart from one another between sidewalls of the chamber body 208. In accordance with certain examples of the disclosure, the plurality of filament-type linear lamps may extend laterally above the chamber body 208 and be longitudinally spaced apart from one another between the injection end 230 and the exhaust end 232 of the chamber body 208. It is contemplated that the lower heater element array 216 be similar to the upper heater element array 214 and additionally be supported below the chamber body 208. It is contemplated that the upper heater element array 214 and the lower heater element array 216 may be operably associated with the system controller 400 (shown in FIG. 1) to control heating of the substrate 2, for example during deposition of the material layer 4 onto the substrate 2. Operable association may be through cooperation with a contact temperature sensor abutting an underside of the substrate support 222, like a thermocouple, and/or a non-contact temperature sensor like a pyrometer supported above or below the chamber body 208.

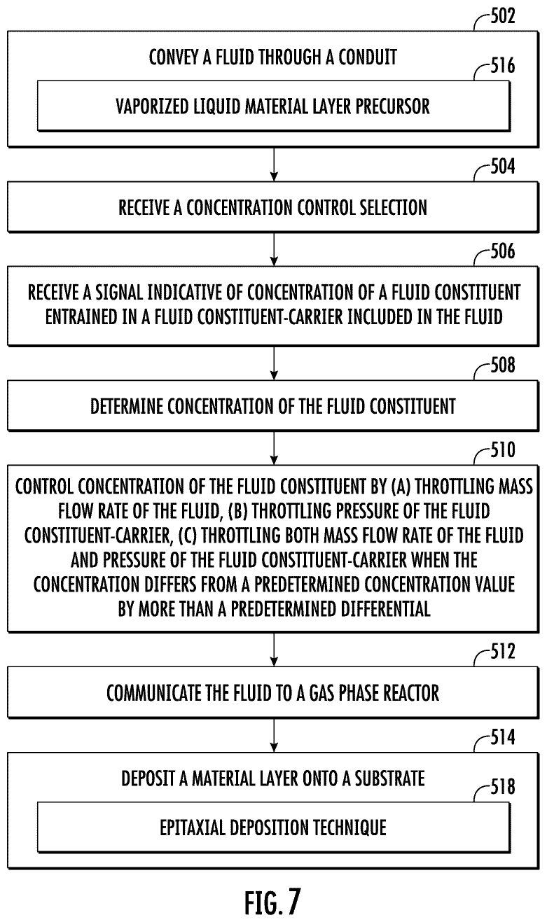

As also shown in FIG. 2 the system controller 400 may include a system controller device interface 402, a system controller processor 404, a system controller user interface 406, and a system controller memory 408. The system controller device interface 402 communicatively couples the system controller 400 to the fluid system 100 through the wired or wireless link 206. The system controller processor 404 is operably connected to the system controller user interface 406 and is disposed in communication with the system controller memory 408. The system controller memory 408 includes a non-transitory machine-readable medium having a plurality of system controller program modules 410 containing instructions that, when read by the system controller processor 404, cause the system controller processor 404 to execute certain operations. Among the operations may be one or more operations of a flow control method 500 (shown in FIG. 7), as will be described, and in this respect may be a computer program product 412. Although shown and described herein as having as including certain elements and having a specific arrangement, it is to be understood and appreciated that the system controller 400 (as well as each controller shown and described herein) may include additional elements and/or omit elements shown and described herein, as well as have different arrangements (e.g., a distributed architecture), and remain within the scope of the present disclosure.

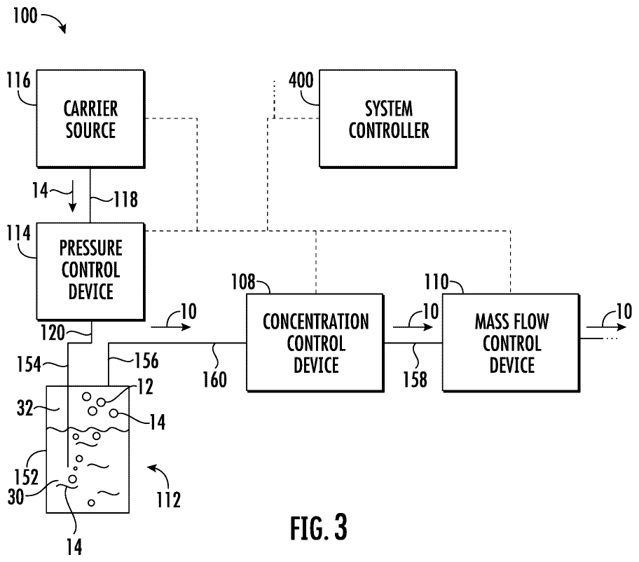

With reference to FIG. 3, the fluid system 100 is shown according to an example of the disclosure. In the illustrated example the fluid system 100 includes a concentration control device (CCD) 108, a mass flow control (MFC) device 110, a liquid vessel 112, a pressure control device (PCD) 114, and a carrier source 116. The carrier source 116 is fluidly coupled to the PCD 114 by a carrier source conduit 118, includes the fluid constituent-carrier 14, and is configured to communicate the fluid constituent-carrier 14 to the PCD 114 and therethrough to the gas phase reactor 200 (shown in FIG. 1) through the liquid vessel 112 and the CCD 108. In certain examples the carrier source 116 may communicate the fluid constituent-carrier 14 to the pressure control device 114 in a gaseous state and in this respect may the fluid constituent-carrier 14 may consist of (or consist essentially of) a gas. In accordance with certain examples the fluid constituent-carrier 14 may include (or consist of or consist essentially of) hydrogen (H₂) gas. In accordance with certain examples, the fluid constituent-carrier 14 may include (or consist of or consist essentially of) an inert fluid. Examples of suitable inert fluids include nitrogen (N₂) gas and noble gases such as argon (Ar) gas, krypton (Kr) gas, and helium (He) gas. It is also contemplated that the fluid constituent-carrier 14 may include a mixture including one or more of the aforementioned fluid constituent-carrier fluids and remain within the scope of the present disclosure.

The liquid vessel 112 is configured to make-up the fluid 10 by vaporizing a liquid fluid constituent charge 30 contained within the liquid vessel 112. More specifically, the liquid vessel 112 is configured to make-up the fluid 10 by vaporizing the liquid fluid constituent charge 30 using a flow of the fluid constituent-carrier 14 received from the carrier source 116 through the PCD 114 and communicate a flow of the fluid 10 to the gas phase reactor 200 (shown in FIG. 1) through the CCD 108 and the MFC device 110. In this respect it is contemplated that the liquid vessel 112 include a vessel body 152, a carrier inlet conduit 154, and a fluid outlet conduit 156. The vessel body 152 is configured to contain the charge of the liquid fluid constituent charge 30 within an interior of the vessel body 152 and may be formed from a stainless steel material, such as 316L stainless or a nickel-based alloy like Hastelloy. It is contemplated that the liquid fluid constituent charge 30 be disposed within an interior of the vessel body 152, that an interior surface of the vessel body 152 and surface of the liquid fluid constituent charge 30 define an ullage space 32 therebetween. It is also contemplated that the ullage space 32 in turn be occupied by a mixture of the fluid constituent 12 in a vapor state and the fluid constituent-carrier 14.

The carrier inlet conduit 154 is configured to introduce the flow of the fluid constituent-carrier 14 into the liquid fluid constituent charge 30 and in this respect fluidly couples the carrier source conduit 118 to the vessel body 152. In further respect, it is also contemplated that the carrier inlet conduit 154 may extend through the ullage space 32 and into the liquid fluid constituent charge 30 toward a lower recess of the vessel body 152 such that the fluid constituent-carrier 14 is introduced into, and bubbles therethrough, the liquid fluid constituent charge 30. It is contemplated that the fluid outlet conduit 156 in turn be configured to communicate a flow of the fluid constituent 12 (e.g., vaporized liquid fluid constituent) entrained in the fluid constituent-carrier 14 to the gas phase reactor 200 (shown in FIG. 1) through the CCD 108 and the MFC device 110. In this respect it is contemplated that the fluid outlet conduit 156 be fluidly coupled to the ullage space 32, fluidly couple the vessel body 152 to CCD 108 through a fluid supply conduit 158, and in turn be fluidly coupled to the gas phase reactor 200 (shown in FIG. 1) by the CCD 108 and the MFC device 110 via the supply conduit 202.

In certain examples the liquid vessel 112 may include one or more of a probe member for acquiring one or more of level, temperature, and pressure from within the vessel body 152. In accordance with certain examples, the vessel body 152 may include a heater and/or a chiller to control temperature of the liquid fluid constituent charge 30, as appropriate for composition of the fluid 10. It is also contemplated that the liquid vessel 112 may include a refill conduit, such as for in-situ or ex-situ refilling of the liquid vessel 112 to restore the liquid fluid constituent charge 30, for example using a liquid level measurement acquired by a level sensor included in the probe member. Examples of suitable liquid vessels include those shown and described in U.S. patent application Ser. No. 19/222,103 to Chitale et al., filed on May 29, 2025, the contents of which is incorporated herein by reference in its entirety.

In certain examples of the present disclosure the liquid fluid constituent charge 30 (and thereby the fluid constituent 12 entrained in the fluid constituent-carrier 14) may include a silicon-containing material layer precursor. In this respect the liquid fluid constituent charge 30 (and the fluid constituent 12) may include (or consist of or consist essentially of) a silicon-containing liquid precursor. For example, the silicon-containing liquid precursor may include at least one silicon atom and one or more additional elements such as, for example, one or more of carbon, nitrogen, oxygen, halogen (e.g., F, Cl, Br, and I), phosphorous, and hydrogen. Examples of suitable silicon-containing liquid precursors include, but are not limited, to a silane (e.g., silane (SiH₄), disilane (Si₂H₆), trisilane (Si₃H₈), and tetrasilane (Si₄H₁₀)), a halosilane (e.g., chlorosilane (SiH₃Cl), dichlorosilane (SiH₂Cl₂), trichlorosilane (SiHCl₃), tetrachlorosilane (SiCl₄), bromosilane (SiH₃Br), iodosilane (SiH₃I), diiodosilane (SiH_{2/2}) hexachlorodisilane (HCDS, Si₂Cl₆), and octachlorotrisilane (OCTS, Si₃Cl₈)), an organosilane (e.g., methylsilane (SiH₃CH₃), dimethylsilane (SiH₂(CH₃)₂), trimethylsilane (SiH(CH₃)₃), and tetramethylsilane (Si(CH₃)₄)), an aminosilane, an oxysilane, and a silylphosphide (e.g., trisilylphosphine (P(SiH₃)₃)).

In accordance certain examples of the disclosure, the liquid fluid constituent charge 30 (and thereby the fluid constituent 12 entrained in the fluid constituent-carrier 14) may include (or consist of or consist essentially of) a germanium-containing liquid precursor. It is contemplated that the germanium-containing liquid precursor may include at least one germanium atom and one or more additional elements such as, for example, one or more of carbon, nitrogen, oxygen, halogen (e.g., F, Cl, Br, and I), and hydrogen. Examples of suitable germanium-containing liquid precursors include, but are not limited, a germane (e.g., germane (GeH₄), digermane (Ge₂H₄), and trigermane (Ge₃H₈)), a halogermane (e.g., dichlorogermane (GeH₂Cl₂), trichlorogermane (GeHCl₃), tetrachlorogermane (GeCl₄), tetrabromogermane (GeBr₄)), a germylsilane (e.g., silylgermane (GeH₃SiH₃)), an organogermane, an aminogermane, and an oxygermane. It is also contemplated that the liquid fluid constituent charge 30 (and the fluid constituent 12) may include (or consist of or consist essentially of) a dopant-containing precursor. The dopant-containing precursor may include a p-type dopant such as boron (B), aluminum (Al), gallium (Ga), and indium (In)) or an n-type dopant (e.g., phosphorous (P), arsenic (As), antimony (Sb), bismuth (Bi), and lithium (Li)). The dopant-containing precursor may include an n-type dopant containing precursors. Non-limiting examples of a suitable arsenic-containing liquid precursors include tertbutylarsine (C₄H₁₁As).

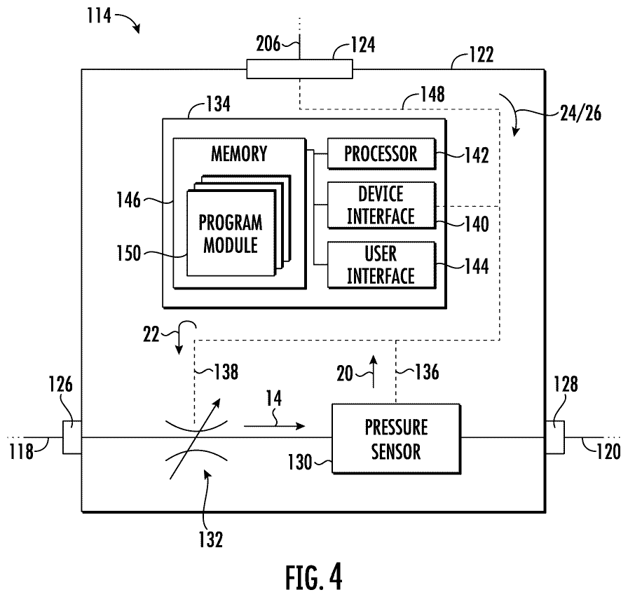

With reference to FIG. 4, the PCD 114 is shown according to an example of the disclosure. It is contemplated that the PCD 114 be configured to control concentration of the fluid constituent 12 communicated to the gas phase reactor 200 (shown in FIG. 1) by throttling pressure of the fluid constituent-carrier 14 communicated to the liquid vessel 112 (shown in FIG. 3) by the carrier source 116 (shown in FIG. 3). In this respect the PCD 114 may be fluidly coupled to the liquid vessel 112 by a carrier supply conduit 120. In the illustrated example the PCD 114 includes a PCD housing 122 with a PCD signal port 124, a PCD inlet port 126 and a PCD outlet port 128, a pressure sensor 130 and pressure control valve 132, and a PCD controller 134. As will be appreciated by those of skill in the art in view of the present disclosure, the PCD 114 may include additional elements, and/or omit elements shown and described herein, as well as have a different arrangement in other examples and remain within the scope of the present disclosure.

The PCD housing 122 seats thereon the PCD signal port 124 and encloses therein the pressure sensor 130, the pressure control valve 132, and the PCD controller 134. The PCD inlet port 126 is fixed to the PCD housing 122 and couples the carrier source conduit 118 to the PCD outlet port 128 through the pressure sensor 130 and the pressure control valve 132. The PCD outlet port 128 couples the PCD inlet port 126 through the pressure sensor 130 and the pressure control valve 132 to the carrier supply conduit 120, and therethrough to the liquid vessel 112. It is contemplated that the pressure sensor 130 be configured to acquire pressure 20 of the fluid constituent-carrier 14 (e.g., a pressure measurement) during flow between the PCD inlet port 126 and the PCD outlet port 128, that the pressure sensor 130 be disposed in communication with the PCD controller 134 through a pressure sensor lead 136, and that the pressure sensor 130 communicate the pressure 20 to the PCD controller 134 via the pressure sensor lead 136. It is also contemplated that the pressure control valve 132 be configured to throttle pressure of the fluid constituent-carrier 14 during flow between the PCD inlet port 126 and the PCD outlet port 128, be arranged fluidly between the PCD inlet port 126 and the PCD outlet port 128, and be operably associated with the PCD controller 134. In this respect the pressure control valve 132 may throttle pressure of the fluid constituent-carrier 14 conveyed to the liquid vessel 112 according to a pressure setting 22 received from the PCD controller 134 via a pressure control valve lead 138.

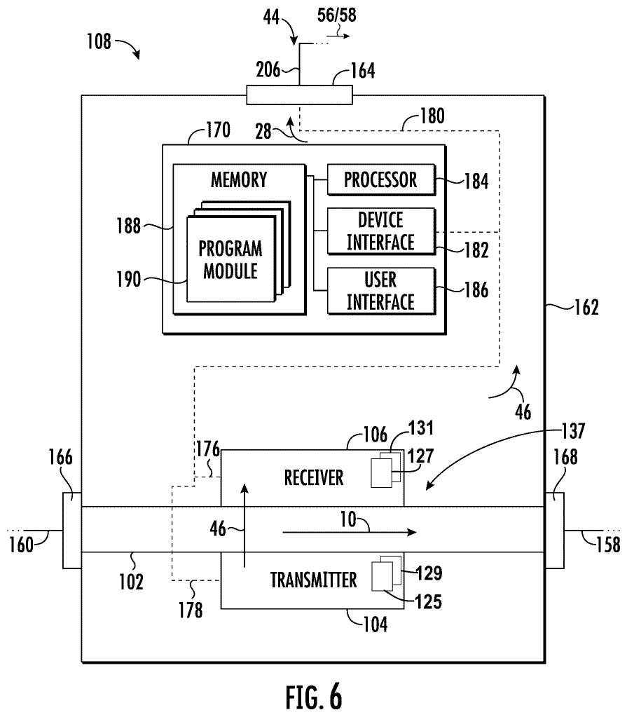

It is contemplated that the PCD controller 134 be configured to control pressure of the fluid constituent-carrier 14 provided by the carrier source 116 to the liquid vessel 112 according to one of a carrier pressure setpoint 24 and a tandem carrier pressure setpoint 26 calculated using a concentration 28 (shown in FIG. 6) of the fluid constituent 12 entrained in the fluid constituent-carrier 14 acquired by the CCD 108 (shown in FIG. 3), for example in a closed-loop regime. In this respect the PCD controller 134 may include a PCD device interface 140, a PCD processor 142, a PCD user interface 144, and a PCD memory 146. The PCD device interface 140 couples the PCD processor 142 to the pressure sensor 130 through the pressure sensor lead 136 and to the pressure control valve 132 through the pressure control valve lead 138. The PCD device interface 140 further couples the PCD processor 142 to the PCD signal port 124 through a PCD signal lead 148 and therethrough the CCD 108 (shown in FIG. 3), the MFC device 110 (shown in FIG. 3), and/or the system controller 400 (shown in FIG. 4 through the wired or wireless link 206. The PCD processor 142 is operably coupled to the PCD user interface 144, for example to receive user input and/or provide user output therethrough, and is disposed in communication with PCD memory 146. The PCD memory 146 in turn includes a non-transitory machine-readable medium having a plurality of PCD program modules 150 recorded thereon that, when read by the PCD processor 142, cause the PCD processor 142 to execute certain operations. Among the operations are operations of the flow control method 500 (shown in FIG. 7), for example to control concentration of the fluid constituent 12 (shown in FIG. 1) conveyed by the fluid system 100 (shown in FIG. 1) by throttling pressure of the fluid constituent-carrier 14, either independently (or in conjunction) with throttling of mass flow rate of the fluid 10, using the one of the carrier pressure setpoint 24 and the tandem carrier pressure setpoint 26 received by the PCD processor 142.

In certain examples the PCD processor 142 may receive the one of the carrier pressure setpoint 24 and the tandem carrier pressure setpoint 26 through the PCD signal port 124, for example from the CCD 108 (shown in FIG. 3), the MFC device 110 (shown in FIG. 3), or the system controller 400 (shown in FIG. 1). It is contemplated that the PCD processor 142 acquire the pressure 20 of the fluid constituent-carrier 14 using the pressure sensor 130, and that the PCD processor 142 compare the pressure 20 to the received one of the carrier pressure setpoint 24 and the tandem carrier pressure setpoint 26. When the pressure 20 differs from the one of the carrier pressure setpoint 24 and the tandem carrier pressure setpoint 26 by less than a predetermined pressure differential, the PCD processor 142 may make no adjustment to pressure of the fluid constituent-carrier 14 provided to the liquid vessel 112 (shown in FIG. 3). and a further pressure measurement acquired and compared to the received one of the carrier pressure setpoint 24 and the tandem carrier pressure setpoint 26. When the pressure 20 differs from the one of the carrier pressure setpoint 24 and the tandem carrier pressure setpoint 26 by more than the predetermined pressure differential, the PCD processor 142 may throttle pressure of the fluid constituent-carrier 14 using the pressure control valve 132, and a further pressure measurement acquired and compared to the received one of the carrier pressure setpoint 24 and the tandem carrier pressure setpoint 26. In certain examples of the present disclosure the PCD 114 may include an electronic pressure controller, such as a 640B series electronic pressure controller, available from MKS Instruments, Inc. of Andover, Massachusetts.

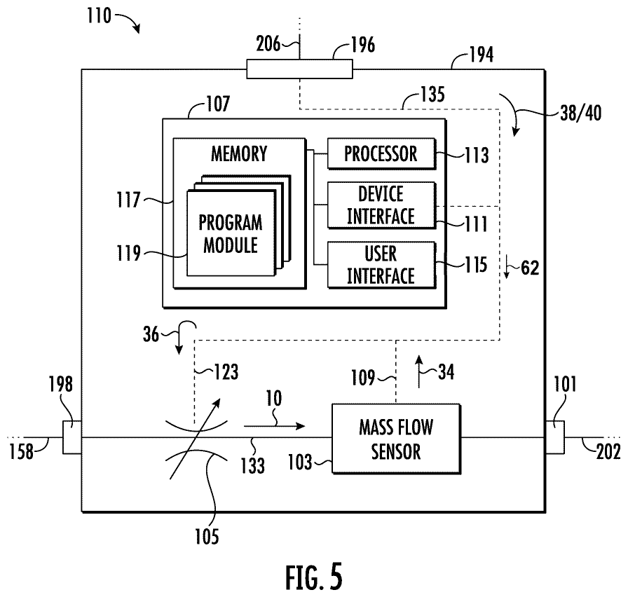

With reference to FIG. 5, the MFC device 110 is shown according to an example of the disclosure. It is contemplated that the MFC device 110 be configured to control mass flow rate of the fluid 10 (e.g., total mass flow rate of both the fluid constituent 12 and the fluid constituent-carrier 14 entraining the fluid constituent 12) conveyed to the gas phase reactor 200 (shown in FIG. 1) by the fluid system 100 and in this respect couples the MFC device 110 (shown in FIG. 3) to the supply conduit 202 via a fluid supply conduit 158. In this respect it is contemplated that the MFC device 110 includes an MFC housing 194 with an MFC signal port 196, an MFC inlet port 198 and an MFC outlet port 101, a mass flow sensor 103, a metering valve 105, and an MFC device controller 107. The MFC housing 194 seats thereon the MFC signal port 196, which couples the MFC device controller 107 to the wired or wireless link 206. The MFC housing 194 further encloses within its interior the mass flow sensor 103, the metering valve 105, and the MFC device controller 107. As will be appreciated by those of skill in the art in view of the present disclosure, the MFC device 110 may include additional elements, and/or omit elements shown and described herein, as well as have a different arrangement in other examples and remain within the scope of the present disclosure.

The MFC inlet port 198 and the MFC outlet port 101 are fixed relative to the MFC housing 194. The MFC inlet port 198 couples the MFC device 110 to the CCD 108 through the fluid supply conduit 158 and therethrough to the liquid vessel 112 (shown in FIG. 3). The MFC outlet port 101 is coupled to the supply conduit 202 and therethrough to the gas phase reactor 200, and couples the MFC inlet port 198 to the supply conduit 202 through the metering valve 105 the mass flow sensor 103. In this respect it is contemplated that the metering valve 105 and the mass flow sensor 103 be fluidly coupled to one another in series within the MFC housing 194, such as along an MFC conduit 133. The metering valve 105 couples the mass flow sensor 103 to the MFC inlet port 198 and may be arranged along the MFC conduit 133. The mass flow sensor 103 may in turn couple the metering valve 105 to the MFC outlet port 101 and may also be arranged along the MFC conduit 133 to convey the fluid 10, for example the fluid constituent 12 (shown in FIG. 1) entrained in the fluid constituent-carrier 14.

The mass flow sensor 103 is configured to acquire a mass flow 34 (e.g., a mass flow rate measurement) of the fluid 10 conveyed to the gas phase reactor 200 (shown in FIG. 1) by the fluid system 100 (shown in FIG. 1). In this respect it is contemplated that the mass flow sensor 103 be coupled to the MFC device controller 107 by a mass flow meter lead 109 and be configured to communicate the mass flow 34 acquired thereby to MFC device controller 107. It is further contemplated that the metering valve 105 be configured to throttle mass flow of the fluid 10 conveyed by fluid system 100 to the to the gas phase reactor 200, for example using a valve member such as a diaphragm, and be operably associated with the MFC device controller 107. Operably association may be through a metering valve setting 36, communicated by the MFC device controller 107, and communicated by the MFC device controller 107 to the metering valve 105 by a metering valve lead 123, which in turn operatively couples the MFC device controller 107 to the metering valve 105.

It is contemplated that the MFC device 110 be configured to control mass flow rate of the fluid 10, e.g., the fluid constituent 12 (shown in FIG. 1) entrained in the fluid constituent-carrier 14, conveyed by the fluid system 100 (shown in FIG. 1) to the gas phase reactor 200 (shown in FIG. 1). It is further contemplated that the MFC device 110 be configured to control mass flow rate of the fluid 10 according to one of a mass flow setpoint 38 and a tandem mass flow setpoint 40 received by the MFC device controller 107 through the MFC signal port 196 via the wired or wireless link 206, for example in a closed-loop regime. In this respect it is contemplated that the MFC device controller 107 be coupled to the MFC signal port 196 by a MFC device signal lead 135 and include an MFC device interface 111, an MFC device processor 113, an MFC device user interface 115, and an MFC device memory 117.

The MFC device interface 111 couples the MFC device processor 113 to the MFC signal port 196 through the MFC device signal lead 135 and therethrough to the CCD 108 (shown in FIG. 3), the MFC device 110 (shown in FIG. 3), and/or the system controller 400 (shown in FIG. 304 through the wired or wireless link 206. The MFC device interface 111 further couples the MFC device processor 113 to the metering valve 105 and the mass flow sensor 103 through the metering valve lead 123 and the mass flow meter lead 109, respectively. The MFC device processor 113 is operably coupled to the MFC device user interface 115, for example to receive user input and/or provide user output therethrough, and is disposed in communication with the MFC device memory 117. The MFC device memory 117 in turn includes a non-transitory machine-readable medium having a plurality of MFC device program modules 119 recorded thereon containing instructions that, when read by the MFC device processor 113, cause the MFC device processor 113 to execute certain operations. Among the operations are operations of the flow control method 500 (shown in FIG. 7), for example to control concentration of the fluid constituent 12 (shown in FIG. 1) conveyed by the fluid system 100 (shown in FIG. 1) to the gas phase reactor 200 (shown in FIG. 1) by throttling mass flow rate of the fluid 10 with the metering valve 105 either independently or in conjunction with throttling of pressure of the fluid constituent-carrier 14 using the one of the mass flow setpoint 38 and the tandem mass flow setpoint 40 received by the MFC device processor 113.

In certain examples the MFC device processor 113 may receive the one of the mass flow setpoint 38 and the tandem pressure setpoint 58 through the MFC signal port 196, for example from the CCD 108 (shown in FIG. 3), the PCD 114 (shown in FIG. 3), or the system controller 400 (shown in FIG. 1). It is contemplated that the MFC device processor 113 further acquire the mass flow 34 of the fluid 10 from the mass flow sensor 103, and that the MFC device processor 113 compare the mass flow 34 to the one of the mass flow setpoint 38 and the tandem mass flow setpoint 40. When the mass flow 34 differs from the one of the mass flow setpoint 38 and the tandem mass flow setpoint 40 by less than a predetermined mass flow rate differential the MFC device processor 113 may make no adjustment to mass flow rate of the fluid 10 conveyed to the gas phase reactor 200 (shown in FIG. 1) using the metering valve 105, and mass flow rate monitoring may thereafter continue by acquiring a further mass flow measurement and making a further comparison. When the mass flow 34 differs from the one of the mass flow setpoint 38 and the tandem mass flow setpoint 40 by more than the predetermined mass flow rate differential the MFC device processor 113 may throttle mass flow rate of the fluid 10 using the metering valve 105. and mass flow rate monitoring may thereafter continue by acquiring a further mass flow measurement and making a further comparison. In certain examples the MFC device 110 may include a GF100 Series MFC device, available from Brooks Instrument LLC of Hatfield, Pennsylvania.

With reference to FIG. 6, the CCD 108 is shown. The CCD 108 is configured to acquire concentration of the fluid constituent 12 entrained in the fluid constituent-carrier 14 conveyed to the gas phase reactor 200 (shown in FIG. 1) by the fluid system 100 (shown in FIG. 1). In this respect it is contemplated that the CCD 108 may fluidly couple the liquid vessel 112 (shown in FIG. 3) and therethrough the PCD 114 (shown in FIG. 3) and the carrier source 116 (shown in FIG. 3) to the MFC device 110 (shown in FIG. 3). In the illustrated example the CCD 108 includes a CCD housing 162 with a CCD signal port 164, a CCD inlet port 166, a CCD outlet port 168, and a CCD conduit 102. As shown and described herein the CCD 108 also includes a concentration sensor 137 including a transmitter 104 and a receiver 106, and a CCD controller 170. Although shown and described herein as including certain elements and having a specific arrangement, it is to be understood and appreciated that the CCD 108 may include additional elements, and/or omit elements shown and described herein, as well as having a different arrangement in other examples and remain within the scope of the present disclosure.

The CCD housing 162 seats thereon the CCD signal port 164 and encloses therein the CCD conduit 102, the concentration sensor 137, and the CCD controller 170. The CCD inlet port 166 is fixed to the CCD housing 162 and couples the fluid source conduit 160 to the CCD conduit 102, the CCD 108 thereby fluidly coupled through the fluid source conduit 160 to the liquid vessel 112 (shown in FIG. 3). It is contemplated that the CCD outlet port 168 also be fixed to the CCD housing 162, and that that the CCD outlet port 168 in turn couple the fluid supply conduit 158 to the CCD conduit 102 such that the CCD 108 is thereby fluidly coupled to the MFC device 110 (shown in FIG. 3). It is further contemplated that the CCD conduit 102 fluidly couple the CCD inlet port 166 to the CCD outlet port 168, and that the concentration sensor 137 in turn be coupled to the CCD conduit 102 for communication therethrough the fluid 10 conveyed by the CCD conduit 102. In this respect it is contemplated that the transmitter 104 be coupled to the CCD conduit 102, for example acoustically or optically, and communicatively coupled to the CCD controller 170 through a transmitter lead 178. The receiver 106 may in turn also be coupled to the CCD conduit 102, and therethrough coupled to the transmitter 104 via the fluid 10 conveyed by the CCD conduit 102, also acoustically or optically in certain examples of the disclosure. It is contemplated that the receiver 106 be communicatively coupled to the CCD controller 170 through a receiver lead 176.

In certain examples the concentration sensor 137 may be an acoustic concentration sensor. In such examples the transmitter 104 may include a transmitter piezoelectric cell 125 and the receiver 106 may include a receiver piezoelectric cell 127, the receiver piezoelectric cell 127 configured to communicate the signal 46 to the CCD controller 170. Examples of suitable acoustic concentration sensors include Piezocon® gas concentration sensors, available from Veeco Instruments, Inc. of Plainview, New York. In accordance with certain examples, the concentration sensor 137 may be an optical concentration sensor. In such examples the transmitter 104 may include an illuminator 129 and the receiver 106 may include an illumination detector 131, the receiver configured to communicate the signal 46 to the CCD controller 170. Examples of suitable optical concentration sensors include T-Series advanced infrared gas analyzers, also available from MKS Instruments. As will be appreciated by those of skill in the art in view of the present disclosure, other types of concentration sensors, for example concentration sensors employing neither acoustic nor optical sensing techniques, may be employed in the CCD 108 and remain within the scope of the present disclosure.

The CCD controller 170 is communicatively coupled to the CCD signal port 164 by a CCD signal lead 180 and therethrough to the wired or wireless link 206. The CCD controller 170 may further be operatively coupled to the concentration sensor 137. In this respect it is contemplated that the CCD controller 170 may be operatively coupled to the transmitter 104 to transmit a signal 46 into the fluid 10 conveyed by the CCD conduit 102 using the transmitter 104, and disposed in communication with the receiver 106 to receive the signal 46 as modulated by the fluid constituent 12 conveyed by the fluid 10 from the receiver 106. In further respect, the CCD controller 170 may be configured to determine concentration of the fluid constituent 12 entrained in the fluid constituent-carrier 14 included in the fluid 10 conveyed by the CCD conduit 102. The CCD controller 170 may further be operatively coupled to both the PCD 114 (shown in FIG. 3) and the MFC device 110 (shown in FIG. 3) to control concentration of the fluid constituent 12 according to a concentration control selection 44 received by the CCD controller 170.

In the illustrated example the CCD controller 170 includes a CCD device interface 182, a CCD processor 184, a CCD user interface 186, and a CCD memory 188. The CCD device interface 182 communicatively couples the CCD processor 184 to the concentration sensor 137, for example to the transmitter 104 through the transmitter lead 178 and the receiver 106 through the receiver lead 176. The CCD device interface 182 also communicatively couples the CCD processor 184 to the wired or wireless link 206 through the CCD signal lead 180 and the CCD signal port 164, and therethrough to one or more of the system controller 400 (shown in FIG. 1), the PCD 114 (shown in FIG. 3), and the MFC device 110 (shown in FIG. 3). The CCD processor 184 may in turn be operatively coupled to the CCD user interface 186, for example to receive user input and/or provide user output therethrough, and is disposed in communication with the CCD memory 188. The CCD memory 188 in turn includes a non-transitory machine-readable medium having a plurality of CCD program modules 190 recorded thereon containing instructions that, when read by the CCD processor 184 cause the CCD processor 184 to execute certain operations. Among the operations are operations of a flow control method 500 (shown in FIG. 7), as will be described. Although shown and described herein as including certain elements and having a specific arrangement, it is to be understood and appreciated that the CCD controller 170 may include additional elements and/or omit elements shown and described herein, or have a different arrangement (e.g., a distributed computing architecture), and remain within the scope of the present disclosure.

In certain examples the instructions recorded on the CCD memory 188 may cause the CCD processor 184 to receive the signal 46 and determine a concentration 28 of the fluid constituent 12 entrained in the fluid constituent-carrier 14 included in the fluid 10 conveyed by the CCD conduit 102. In accordance with certain examples, the instructions on the CCD memory 188 may also cause the CCD processor to receive the concentration control selection 44, for example from the system controller 400 (shown in FIG. 1) through the wired or wireless link 206. It is contemplated that, in certain examples, the instructions recorded on the CCD memory 188 may cause the CCD processor 184 to determine the mass flow setpoint 38 (shown in FIG. 5) and communicate the mass flow setpoint 38 to the MFC device 110 when the concentration control selection 44 received by the CCD processor 184 is (a) mass flow rate of the fluid to throttle mass flow rate of the fluid 10 conveyed by the CCD conduit 102. It is also contemplated that, in accordance with certain examples, the instructions recorded on the CCD memory 188 may cause the CCD processor 184 to determine the pressure setpoint 24 (shown in FIG. 4) when the concentration control selection 44 received by the CCD processor 184 is (b) pressure of the fluid constituent-carrier and communicate the pressure setpoint 24 to the PCD 114 (shown in FIG. 3) to throttle pressure of the fluid constituent-carrier. It is further contemplated that the instructions recorded on the CCD memory 188 may cause the controller 184 to determine both the tandem mass flow setpoint 40 (shown in FIG. 4) and the tandem pressure setpoint 26 (shown in FIG. 5) when the concentration control selection 44 received by the CCD 108 is (c) both mass flow rate of the fluid and pressure of the fluid constituent-carrier to throttle both the mass flow rate of the fluid 10 and the pressure of the fluid constituent-carrier 14 (shown in FIG. 1). The aforementioned setpoints may be retrieved, for example, from a lookup table recorded in one or more of the plurality of CCD program modules 190 recorded on the CCD memory 188 having concentration-to-setpoint associations specific for each concentration control selections (a)-(c). It is also contemplated that instructions recorded on the CCD memory 188 may cause the CCD processor 184 to communicate the concentration 28 to another processor, e.g., the system controller processor 404 (shown in FIG. 2), and that other processor determined and communicate the aforementioned setpoint to the MFC device 110 and the PCD 114 according to the concentration control selection 44, and remain within the scope of the present disclosure.

With reference to FIG. 7 to FIG. 11, the flow control method 500 is shown according to an example of the present disclosure. As shown in FIG. 7, the flow control method 500 includes conveying a fluid through a conduit, e.g., the fluid 10 (shown in FIG. 1) through the CCD conduit 102 (shown in FIG. 6), as shown with box 502. A concentration control selection may be received at a user interface, e.g., the concentration control selection 44 (shown in FIG. 6) received at the system controller user interface 406 (shown in FIG. 2), and a signal indicative of concentration of a fluid constituent entrained in a fluid constituent-carrier included in the fluid received from a concentration sensor, e.g., the signal 46 (shown in FIG. 6) received from the concentration sensor 137 (shown in FIG. 6), as shown with box 504 and box 506. It is contemplated that concentration of a fluid constituent entrained within a fluid constituent-carrier included in the fluid may be determined using the signal, e.g., concentration of the fluid constituent 12 (shown in FIG. 1); and that concentration of the fluid constituent be controlled by (a) throttling mass flow rate of the fluid, (b) throttling pressure of the fluid constituent-pressure, and (c) throttling both mass flow rate of the fluid and pressure of the fluid constituent-carrier according to the received concentration control selection and the determined concentration; as shown with box 510. In this respect it is contemplated that concentration acquired using the signal may be compared to a predetermined concentration value, and that concentration of the fluid constituent entrained in the fluid constituent-carrier may be controlled by throttling either (or both) mass flow rate of the fluid and pressure of the fluid constituent-carrier when the concentration differs from the predetermined concentration value by more than a predetermined concentration differential according to the received concentration control selection.

In certain examples fluid constituent may be a vaporized liquid material layer precursor, as shown with box 512. In accordance with certain examples, the conduit may convey the fluid to a gas phase reactor, e.g., the gas phase reactor 200 (shown in FIG. 1) as shown with box 514. It is also contemplated that a material layer may be deposited onto a substrate supported within the gas phase reactor, e.g., the material layer 4 (shown in FIG. 1) onto the substrate 2 (shown in FIG. 1), and that the material layer may be deposited using an epitaxial deposition technique, as shown with box 516 and box 518. In accordance with certain examples, the vaporized material layer precursor may include (or consist of or consist essentially of) a vaporized liquid silicon-containing material layer precursor, as also shown with box 512. In accordance with certain examples, the vaporized material layer precursor may include (or consist of or consist essentially of) a vaporized liquid germanium-containing material layer precursor, as further shown with box 512. It is also contemplated that the vaporized material layer precursor may include (or consist of or consist essentially of) a vaporized liquid dopant-containing material layer precursor, as additionally shown with box 512. As will be appreciated by those of skill in the art in view of the present disclosure, the flow control method may be employed with other types of fluids and remain within the scope of the present disclosure.

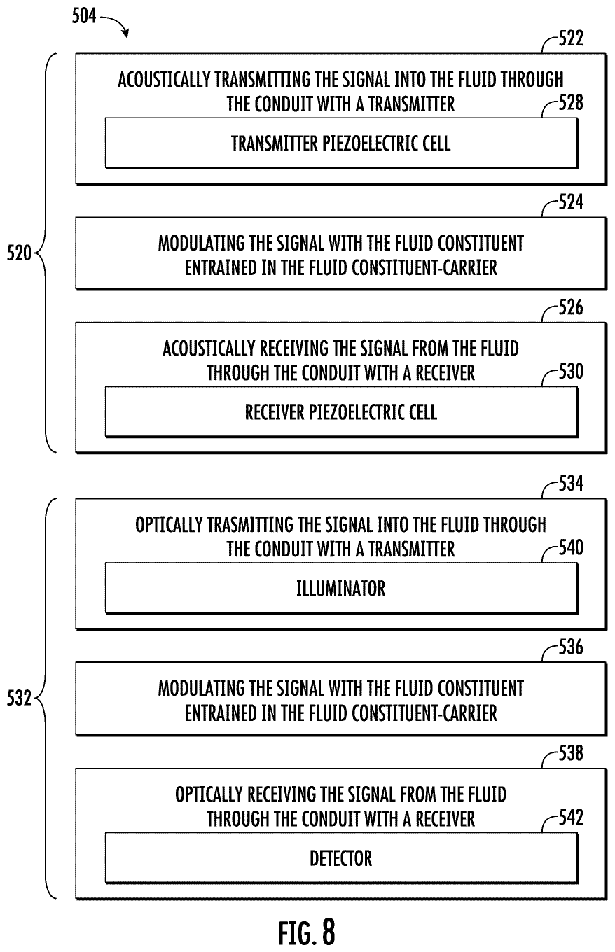

As shown in FIG. 8, receiving 504 the signal may include acquiring the signal using a transmitter and a receiver included in the concentration sensor, e.g., the transmitter 104 (shown in FIG. 6) and the receiver 106 (shown in FIG. 6), using an acoustic technique or an optical technique, as shown with bracket 520 and bracket 532. Acoustically acquiring concentration of the fluid constituent may include transmitting the signal acoustically into the fluid conveyed by the conduit through the conduit using the transmitter, as shown with box 522. The acoustic signal may be acoustically modulated within the conduit by the fluid conveyed by the fluid, as shown by box 524, and the modulated acoustic signal thereafter received from the fluid by the receiver through the conduit, as shown with box 526. The acoustic signal may thereafter be communicated electrically by the receiver to a processor, e.g., the CCD processor 184 (shown in FIG. 6), as also shown with box 526, and the processor may in turn determine concentration of the fluid constituent with the signal. In certain examples the signal may be acoustically transmitted by a transmitter piezoelectric cell, as shown with box 528, and acoustically received by a receiver piezoelectric cell, as shown with box 530. It is also contemplated that the signal may be acoustically transmitted and received by a common piezoelectric cell, as also shown with box 528 and box 530.

Optically acquiring concentration of the fluid constituent may include transmitting the signal optically into the fluid conveyed by the conduit through the conduit using the transmitter, as shown with box 534. The optical signal may be optically modulated within the conduit by the fluid conveyed by the fluid, as shown by box 536, and the modulated optical signal may thereafter be optically received from the fluid by the receiver through the conduit, as shown with box 538. The signal may thereafter be communicated electrically to the processor by the receiver, as also shown with box 538, and the processor may determine concentration using the signal. In certain examples the optical signal may be transmitted using an illuminator arranged within the transmitter, as shown with box 540. In accordance with certain examples, the signal may be received by an illumination photodetector, such as a photodetector, arranged within the receiver, as shown with box 542.

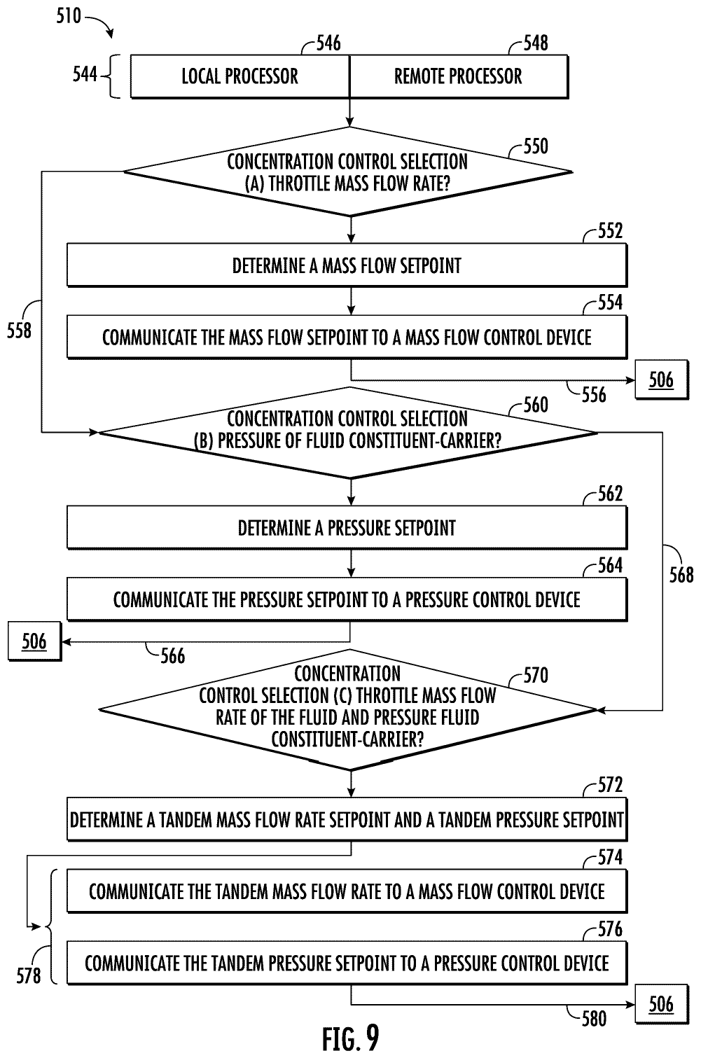

As shown in FIG. 9, controlling 510 concentration of the fluid constituent may be accomplished locally or remotely with respect to the concentration control device, as shown with box 544. In certain examples throttling of either (or both) mass flow rate of the fluid and pressure of the fluid constituent-carrier may be accomplished by locally by determining either (or both) a mass flow setting of the fluid and a pressure of the fluid constituent-carrier using the CCD processor, and thereafter communicate to a mass flow control device and/or a pressure control device, e.g., the MFC device 110 (shown in FIG. 3) and/or the PCD 114 (shown in FIG. 3), as shown with box 546. In accordance with certain examples, throttling of either (or both) mass flow rate of the fluid and pressure of the fluid constituent-carrier may be accomplished by remotely relative to the concentration control device using the concentration of the fluid constituent determined by the CCD processor, as shown with box 548. In this respect the concentration may be communicated through a wired or wireless link, e.g., the wired or wireless link 206 (shown in FIG. 1), communicatively coupling the CCD processor to a remote processor, e.g., the system controller processor 404 (shown in FIG. 4), as also shown with box 548. The remote processor may then determine either (or both) a mass flow setting of the fluid and a pressure of the fluid constituent-carrier using the CCD processor, and remote processor in turn communicate the mass flow setpoint and the pressure setpoint to the mass flow control device and/or a pressure control device, as further shown with box 548.

Controlling 510 concentration of the fluid constituent conveyed by the conduit may differ according to the concentration control selection. For example, a mass flow setpoint may be determined using the concentration when the concentration control selection is (a) throttling mass flow rate of the fluid, e.g., the mass flow setpoint 38 (shown in FIG. 4), as shown with box 550 and box 552. The calculated mass flow setpoint may be communicated to the MFC device, as shown with box 554, and concentration of the fluid constituent conveyed by the conduit continually monitored using the mass flow setpoint until a further acquired concentration indicates that the mass flow setpoint required further adjustment, as shown with arrow 556 and box 506. Alternatively, a pressure control setpoint may be determined using the concentration, e.g., the pressure setpoint 62 (shown in FIG. 5), as shown with arrow 558, box 560, and box 562. The pressure setpoint may be communicated to the pressure controller, as shown with box 564, and monitoring of pressure of the fluid constituent-carrier continue using the pressure setpoint, for example using a closed-loop control regime, as shown with arrow 566 and box 506. Notably, the pressure control setpoint employed to control pressure of the fluid constituent-carrier may remain unchanged when the received concentration control selection is (a) throttling mass flow rate of the fluid, as also shown with box 550, and the mass flow setpoint employed to control mass flow rate of the fluid may remain unchanged when the received concentration control selection is (b) throttling pressure of the fluid constituent-carrier, as further shown with box 560. As will be appreciated by those of skill in the art in view of the present disclosure, this enables employment of a concentration controller with a singular hardware configuration to be employed in fluid systems conveying fluids amenable to concentration control regimes requiring either fluid mass flow control or fluid constituent-carrier pressure control, simplifying the arrangement of the fluid system and/or semiconductor processing systems employing such fluid systems.

It is contemplated that a tandem mass flow setpoint and a tandem pressure setpoint be determined when the concentration control selection (c) throttling both mass flow rate of the fluid and pressure of the fluid constituent-carrier is received, e.g., the tandem mass flow setpoint 56 (shown in FIG. 6) and the tandem pressure setpoint 58 (also shown in FIG. 6), as shown with arrow 568, box 570, and box 572. The tandem mass flow setpoint may be communicated to the MFC device, as shown with box 574. The tandem pressure setpoint may be communicated to the pressure control device, as shown with box 576, and monitoring of both mass flow rate of the fluid and pressure of the fluid constituent-carrier continue using the tandem mass flow setpoint and the tandem pressure setpoint pressure setpoint continues, for example using closed-loop control regimes, as shown with arrow 568 and box 506. In certain examples the tandem mass flow setpoint and the tandem pressure setpoint may be communicated to the MFC device and the pressure control device as substantially the same time, as shown with bracket 580. In accordance with certain examples, the tandem mass flow setpoint determined when the concentration control selection (c) throttling both mass flow rate of the fluid and pressure of the fluid constituent-carrier is received than when the concentration control selection (a) throttling mass flow rate of the fluid is received, and the tandem pressure setpoint determined when the concentration control selection (c) throttling both mass flow rate of the fluid and pressure of the fluid constituent-carrier is received than when the concentration control selection (b) throttling pressure of the fluid constituent-carrier is received, as also shown with box 576 and box 578. As will be appreciated by those of the skill in the art in view of the present disclosure, adjusting both mass flow rate of the fluid and pressure of the fluid constituent-carrier may limit the range of mass flow rate changes made by the MFC device. As will also be appreciated by those of skill in the art in view of the present disclosure, adjusting both mass flow rate of the fluid and pressure of the fluid constituent-carrier may also limit cost the fluid system, for example by enable use of MFC devices having relatively narrow mass flow rate control ranges wherein mass flow rate is linear in relation to the movement range of the valve member within the metering valve included in the MFC device.

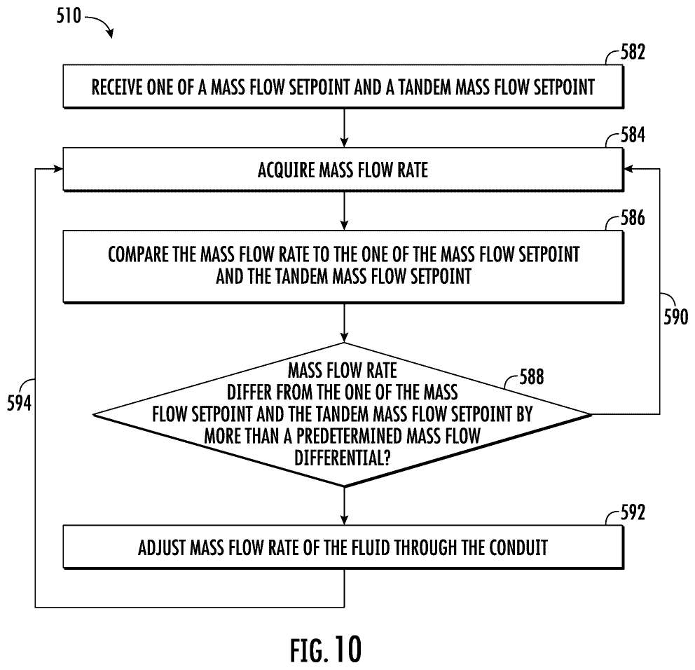

As shown in FIG. 10, controlling 510 mass flow rate of the fluid constituent conveyed by the conduit using the one of the mass flow setpoint and the tandem mass flow setpoint using a closed loop control regime is shown. As shown with box 582, it is contemplated that the mass flow setpoint and the tandem mass flow setpoint be received by a MFC device fluidly coupled to the conduit, for example the MFC device 110 (shown in FIG. 3). As shown with box 584, the MFC device may in turn acquire mass flow rate of the fluid conveyed by the conduit, for example using a mass flow meter included in the MFC device located fluidly downstream of the conduit. The acquired mass flow rate may be compared with the one of the mass flow setpoint and the tandem mass flow setpoint and no action taken when mass flow rate of the fluid differs from the one of the mass flow setpoint and the tandem mass flow setpoint by less than a predetermined mass flow rate differential, as shown with box 588. When mass flow rate of the fluid differs from the one of the mass flow setpoint and the tandem mass flow setpoint by more than the predetermined mass flow rate differential, mass flow rate of the fluid may be throttled, as shown with box 592, for example using a metering valve included in the MFC device. It is contemplated that monitoring of the mass flow rate may thereafter continue in either event by acquiring a further mass flow rate and comparing the subsequently acquired mass flow rate to the one of the mass flow setpoint and the tandem mass flow setpoint, as shown with arrow 590 and arrow 594.

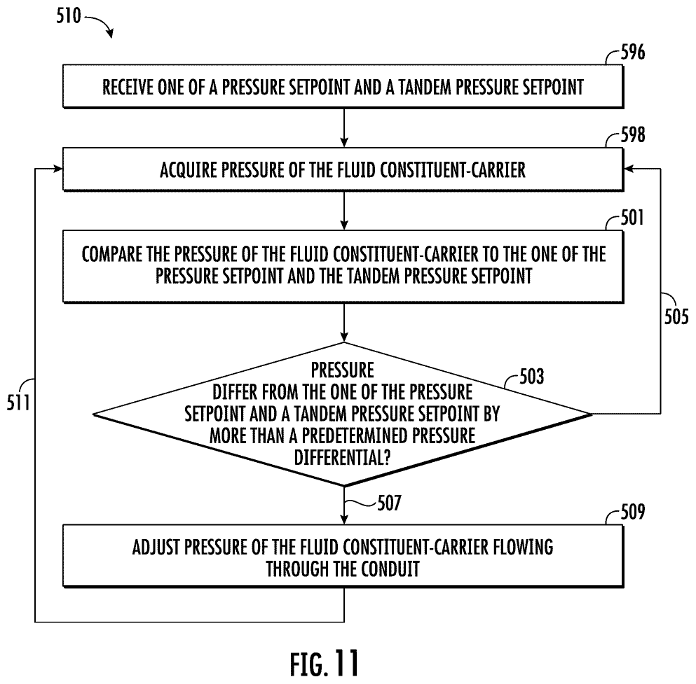

As shown in FIG. 11, controlling 510 mass flow rate of the fluid constituent conveyed by the conduit using the one of the pressure setpoint and the tandem pressure setpoint using a closed loop control regime is shown. As shown with box 596, one of the pressure setpoint and the tandem pressure setpoint (w may the received by a pressure control device, for example the pressure control device 114 (shown in FIG. 3). As shown with box 598, the pressure control device may in turn acquire pressure of the fluid constituent-carrier, for example using a pressure sensor included in the pressure controlling and in communication with a flow of a fluid constituent-carrier employed to vaporized liquid fluid constituent and carry the vaporized liquid fluid constituent to the conduit. It is contemplated that the acquired pressure may be compared to the one of the pressure setpoint and the tandem pressure setpoint, as shown with box 501 and box 503, and that no action be taken when the pressure of the fluid constituent-carrier differ from the one of the pressure setpoint and the tandem pressure setpoint by less than a predetermined pressure differential, as shown with arrow 505. It is also contemplated that the pressure of the fluid constituent-carrier may be throttled with the acquired pressure differs from the one of the pressure setpoint and the tandem pressure setpoint by more than the predetermine pressure differential, as shown with arrow 507 and box 509. Pressure monitoring may thereafter continue, as shown with arrow 511.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

What is claimed:

1. A fluid system, comprising:
a conduit;
a concentration sensor coupled to the conduit; and
a processor disposed in communication with the concentration sensor and responsive to instructions recorded on a memory to:
receive a concentration control selection;
receive a signal indicative of concentration of a fluid constituent entrained in a fluid constituent-carrier in a fluid conveyed by the conduit;
determine a concentration of the fluid constituent; and
control the concentration of the fluid constituent by throttling one of (a) mass flow rate of the fluid, (b) pressure of the fluid constituent-carrier, and (c) the mass flow rate of the fluid and the pressure of the fluid constituent-carrier based on the concentration control selection when the determined concentration differs from a predetermined concentration value by more than a predetermined concentration differential.

2. The fluid system of claim 1, wherein the concentration sensor comprises:
an acoustic transmitter coupled to the conduit and
an acoustic receiver coupled to the acoustic transmitter by the conduit.

3. The fluid system of claim 1, wherein the concentration sensor comprises:
an illuminator coupled to the conduit; and
a detector coupled to the illuminator by the conduit.

4. The fluid system of claim 1, further comprising:
a liquid vessel fluidly coupled to the concentration sensor;
a pressure control device fluidly coupled to the liquid vessel and therethrough to the concentration sensor; and
a mass flow control device fluidly coupled to the concentration sensor and therethrough to the pressure control device by the liquid vessel.

5. The fluid system of claim 4, wherein the concentration sensor is operably coupled to the pressure control device and the mass flow control device.

6. The fluid system of claim 4, further comprising:
a liquid material layer precursor contained in the liquid vessel;
a carrier source including a carrier fluid, the carrier source fluidly coupled to the liquid vessel by the pressure control device;
wherein the liquid material layer precursor comprises a silicon-containing material layer precursor, a germanium-containing material layer precursor, or a dopant-containing material layer precursor; and
wherein the carrier source is configured to communicate a flow of the carrier fluid to the liquid vessel to vaporize the liquid material layer precursor contained in the liquid vessel.

7. The fluid system of claim 4, further comprising a gas phase reactor having a single-wafer crossflow architecture coupled to the mass flow control device and therethrough to the pressure control device through the concentration sensor and the liquid vessel.

8. The fluid system of claim 4, further comprising a wired or wireless link communicatively coupling the concentration sensor to the pressure control device and the mass flow control device.

9. The fluid system of claim 1, further comprising a mass flow control device fluidly coupled to the concentration sensor, and wherein the instructions recorded on the memory further cause the processor to:
compare the concentration to a predetermined concentration value; and
throttle a mass flow rate of the fluid conveyed by the conduit when the determined concentration differs from the predetermined concentration value by more than a predetermined concentration differential when the received concentration control selection is the (a) mass flow rate of the fluid.

10. The fluid system of claim 9, wherein throttling the mass flow rate of the fluid comprises:
determining a mass flow setpoint using the concentration; and
communicating the mass flow setpoint to the mass flow control device.

11. The fluid system of claim 1, further comprising a pressure control device fluidly coupled to the concentration sensor, and wherein the instructions further cause the processor to:
compare the concentration to a predetermined concentration value; and
throttle a pressure of the fluid constituent-carrier when the concentration differs from the predetermined concentration value by more than the predetermined concentration differential when the received concentration control selection is the (b) pressure of the fluid constituent-carrier.

12. The fluid system of claim 11, wherein throttling the pressure of the fluid constituent-carrier comprises:
determining a pressure setpoint using the concentration; and
communicating the pressure setpoint to the pressure control device.

13. The fluid system of claim 1, further comprising:
a pressure control device fluidly coupled to the concentration sensor;
a mass flow device fluidly coupled to the pressure control device through the concentration sensor; and
wherein the instructions recorded on the memory further cause the processor to:
compare the concentration to a predetermined concentration value; and
throttle both the mass flow rate of the fluid and the pressure of the fluid constituent-carrier when the concentration differs from the predetermined concentration value by more than the predetermined concentration differential when the received concentration control selection is the (c) the mass flow rate of the fluid and the pressure of the fluid constituent-carrier.

14. The fluid system of claim 13, wherein throttling both the mass flow rate of the fluid and the pressure of the fluid constituent-carrier comprises:
determining a tandem mass flow setpoint and a tandem pressure setpoint using the concentration; and
communicating the tandem mass flow setpoint to the mass flow device and the tandem pressure setpoint to the pressure control device.

15. The fluid system of claim 1, further comprising:
a concentration control device housing enclosing the concentration sensor; and
a wired or wireless link coupled to the concentration sensor coupling the concentration sensor to the processor.

16. A semiconductor processing system, comprising:
a fluid system as recited in claim 1, further comprising:
a liquid vessel fluidly coupled to the conduit; and
a silicon-containing material layer precursor in a liquid state contained within the liquid vessel;
a gas phase reactor coupled to the conduit;
an exhaust source coupled to the gas phase reactor and therethrough to the fluid system; and
a system controller operatively coupled to the gas phase reactor, wherein the system controller includes the processor.

17. A flow control method, comprising:
at a fluid system including a conduit, a concentration sensor coupled to the conduit, and a processor disposed in communication with the concentration sensor and responsive to instructions recorded on a memory,
receiving, at the processor, a concentration control selection;
receiving, at the processor, a signal indicative of concentration of a fluid constituent entrained in a fluid constituent-carrier in a fluid conveyed by the conduit;
determining, using the processor, a concentration of the fluid constituent; and
controlling the concentration of the fluid constituent conveyed by the conduit by throttling one of (a) mass flow rate of the fluid, (b) pressure of the fluid constituent-carrier, and (c) the mass flow rate of the fluid and the pressure of the fluid constituent-carrier based on the concentration control selection when the determined concentration differs from a predetermined concentration value by more than a predetermined concentration differential.

18. The flow control method of claim 17, wherein the fluid constituent includes a vaporized liquid silicon-containing material layer precursor, a vaporized liquid germanium-containing material layer precursor, and/or a vaporized liquid dopant-containing material layer precursor.

19. The flow control method of claim 17, wherein the fluid constituent comprises a vaporized liquid material layer precursor; the method further comprising:
communicating the fluid constituent to a gas phase reactor using the conduit; and
depositing a material layer onto a substrate supported in the gas phase reactor using the vaporized liquid material layer precursor using an epitaxial deposition technique.

20. A computer program product, comprising:
a non-transitory machine-readable medium having a plurality of program modules recorded thereon that, when read by a processor, cause the processor to:
receive a concentration control selection;
receive, at the processor, a signal indicative of concentration of a fluid constituent entrained in a fluid constituent-carrier in a fluid conveyed by a conduit from a concentration sensor coupled to the conduit and disposed in communication with the concentration sensor;
determine concentration of the fluid constituent; and
control the concentration of the fluid constituent conveyed by the conduit by throttling one of (a) mass flow rate of the fluid, (b) pressure of the fluid constituent-carrier, and (c) the mass flow rate of the fluid and the pressure of the fluid constituent-carrier based on the concentration control selection when the concentration differs from a predetermined concentration value by more than a predetermined concentration differential.
